(19) United States
(12) Patent Application Publication
(10) Pub. No.: US 2011/0073876 A1
(43) Pub. Date: Mar. 31, 2011

(54) LIGHT-EMITTING DEVICE AND DISPLAY

(75) Inventors: Hironori Yoshida, Miyagi (JP); Masashi Enomoto, Tokyo (JP); Yuichi Arisaka, Miyagi (JP); Hitoshi Wako, Miyagi (JP)

(73) Assignee: SONY CORPORATION, Tokyo (JP)

(21) Appl. No.: 12/886,736

(22) Filed: Sep. 21, 2010

(30) Foreign Application Priority Data
Sep. 29, 2009 (JP) P2009-224899

(51) Int. Cl. H01L 33/38; H01L 33/08

(52) U.S. Cl. 257/88; 257/99; 257/E33.005

(57) ABSTRACT

A light-emitting device allowed to obtain polarized light without increasing the number of components or the thickness thereof, and a display including the light-emitting device are provided. The light-emitting device includes: a light-emitting element including, on a substrate, a first electrode, a light-emitting layer and a second electrode in order from the substrate. The substrate has, on a surface facing the first electrode, a first concavo-convex structure including a plurality of strip-shaped protrusion sections with a width equal to or smaller than an upper wavelength limit of visible light, and the first electrode, the light-emitting layer and the second electrode each have, on a surface opposite to a surface facing the substrate, a second concavo-convex structure imitating the protrusion sections of the first concavo-convex structure.

### CROSS REFERENCES TO RELATED APPLICATIONS

The present application claims priority to Japanese Priority Patent Application JP 2009-224899 filed in the Japan Patent Office on Sep. 29, 2009, the entire content of which is hereby incorporated by reference.

### BACKGROUND

The present application relates to a light-emitting device including a light-emitting element such as an organic electroluminescence element (an organic EL element), and a display including the light-emitting device.

Cold cathode fluorescent lamps have been heretofore used widely as backlights of liquid crystal displays. The cold cathode fluorescent lamps have superior characteristics including an emission wavelength range, luminance and the like, but a reflective plate, a light guide plate or the like is necessary to irradiate a whole surface of a liquid crystal display with light, so the cold cathode fluorescent lamps have issues to be solved such as an increase in component cost and high power consumption. Therefore, in recent years, a liquid crystal display using an organic EL element as a backlight has been proposed as described in Japanese Unexamined Patent Application Publication No. 10-125461. The organic EL element is a light-emitting element, and has a number of advantages such as manufacturability by a thin film process, low power consumption and a wide range of wavelength selectivity.

Typically, the organic EL element has a configuration in which a transparent electrode as an anode, a light-emitting layer including an organic EL layer, and a reflective electrode as a cathode are laminated on a transparent substrate such as a glass substrate. The transparent electrode is made of, for example, ITO (Indium Tin Oxide) or the like, and the reflective electrode is made of Al (aluminum) or the like. The light-emitting layer has, for example, a laminate configuration including a hole transport layer, the organic EL layer and an electron transport layer.

In the organic EL element with such a configuration, when a DC voltage is applied between the transparent electrode and the reflective electrode, holes injected from the transparent electrode are introduced into the organic EL layer through the hole transport layer, and electrons injected from the reflective electrode are introduced into the organic EL layer through the electron transport layer. In the organic EL layer, light with a predetermined wavelength is generated by the recombination of the holes and the electrons introduced into the organic EL layer, and the generated light is emitted to outside through the transparent electrode and the transparent substrate.

### SUMMARY

In an organic EL element of this kind, light generated in the light-emitting layer is typically non-polarized light unless a material of the light-emitting layer has anisotropy. Therefore, most of the light generated in the light-emitting layer is absorbed by a polarizer of a liquid crystal display panel. Therefore, it is considered to arrange a reflective polarizer between a backlight and the liquid crystal display panel. However, in such a case, the number of components is increased, and the thickness of the display is increased.

It is desirable to provide a light-emitting device allowed to obtain polarized light without increasing the number of components or a thickness thereof, and a display including the light-emitting device.

According to an embodiment, there is provided a light-emitting device including: a light-emitting element including, on a substrate, a first electrode, a light-emitting layer and a second electrode in order from the substrate. The substrate has, on a surface facing the first electrode, a first concavo-convex structure including a plurality of strip-shaped protrusion sections with a width equal to or smaller than an upper wavelength limit of visible light. The first electrode, the light-emitting layer and the second electrode each have, on a surface opposite to a surface facing the substrate, a second concavo-convex structure imitating the protrusion sections of the first concavo-convex structure.

According to an embodiment, there is provided a display including: a display panel driven based on an image signal; and a light-emitting device emitting light which is applied to the display panel. The light-emitting device includes a substrate, and includes, on a surface opposite to a surface facing the display panel of the substrate, a first electrode, a light-emitting layer and a second electrode in order from the substrate. The substrate has, on a surface facing the first electrode, a first concavo-convex structure including a plurality of strip-shaped protrusion sections with a width equal to or smaller than an upper wavelength limit of visible light. The first electrode, the light-emitting layer and the second electrode each have, on a surface opposite to a surface facing the substrate, a second concavo-convex structure imitating the protrusion sections of the first concavo-convex structure.

In the light-emitting device and the display according to the embodiment, the first concavo-convex structure including a plurality of strip-shaped protrusion sections with a width equal to or smaller than an upper wavelength limit of visible light is arranged on a surface facing the first electrode of the substrate. The first electrode, the light-emitting layer and the second electrode each have, on a surface opposite to a surface facing the substrate, the second concavo-convex structure imitating the protrusion sections of the first concavo-convex structure. Thereby, light generated in the light-emitting layer is converted into polarized light by the first concavo-convex structure on the surface of the substrate or the second concavo-convex structures of the first electrode, the light-emitting layer and the second electrode.

In the light-emitting device and the display according to the embodiment, light generated in the light-emitting layer is converted into polarized light by the first concavo-convex structure on the surface of the substrate or the second concavo-convex structures of the first electrode, the light-emitting layer and the second electrode. Thereby, light emitted from the light-emitting element is allowed to be converted into polarized light, so without increasing the number of components or the thickness of the light-emitting device, polarized light is obtainable. As a result, in a display using polarized light (typically a liquid crystal projector, a liquid crystal television, a liquid crystal monitor or the like which will be described later) or an illuminating device, higher luminance and higher contract is achievable.

Additional features and advantages are described herein, and will be apparent from the following Detailed Description and the figures.

### BRIEF DESCRIPTION OF THE FIGURES

FIG. 1 is a sectional view of a display according to a first embodiment.

FIGS. 2A and 2B are a perspective view and a sectional view of a light-emitting device included in an illuminating device illustrated in FIG. 1.

FIG. 3 is a schematic view for describing a function of the light-emitting device in FIGS. 2A and 2B.

FIG. 4 is a relationship diagram between current density and luminance.

FIG. 5 is a relationship diagram between a polarization component and power efficiency.

FIG. 6 is a relationship diagram between a pitch and an extinction ratio.

FIG. 7 is a relationship diagram between an aspect ratio and an extinction ratio.

FIG. 8 is a configuration diagram of a projector according to a second embodiment.

FIG. 9 is a sectional view of a modification of the light-emitting device in FIG. 2.

### DETAILED DESCRIPTION

Preferred embodiments will be described in detail below referring to the accompanying drawings. Descriptions will be given in the following order.

1. First Embodiment (display)

2. Second Embodiment (projector)

### First Embodiment

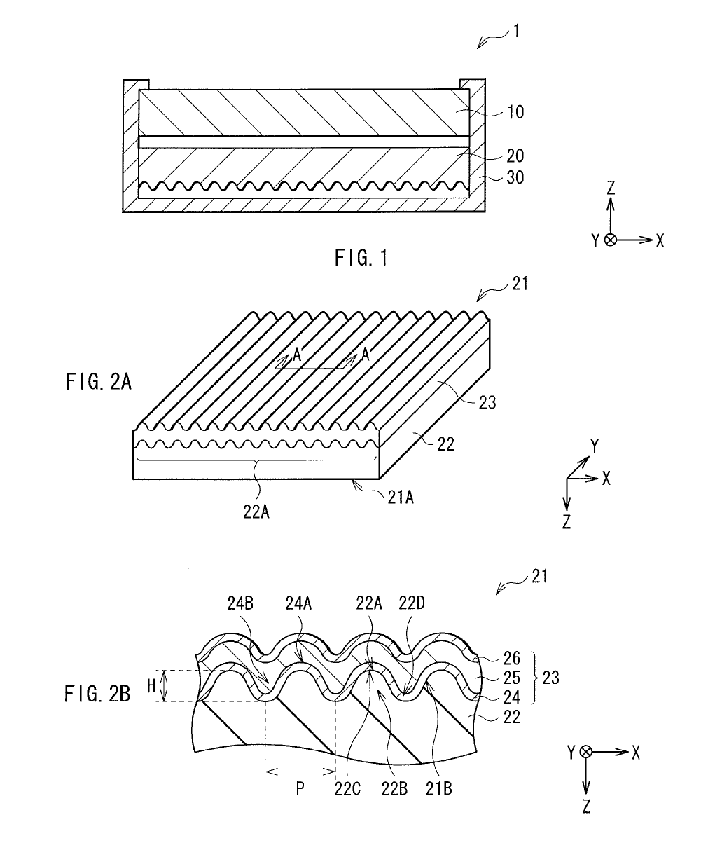

FIG. 1 illustrates an example of a schematic configuration of a display 1 according to a first embodiment. The display 1 includes a liquid crystal display panel 10 (a display panel), an illuminating device 20 arranged on a back surface of the liquid crystal display panel 10, an enclosure 30 supporting the liquid crystal display panel 10 and the illuminating device 20, and a drive circuit (not illustrated) driving the liquid crystal display panel 10 to display a picture. In the display 1, a front surface of the liquid crystal display panel 10 is oriented toward a viewer (not illustrated).

Liquid crystal display panel 10

The liquid crystal display panel 10 displays a picture. The liquid crystal display panel 10 is, for example, a transmissive display panel in which each pixel is driven in response to a picture signal, and has a configuration in which a liquid crystal layer is sandwiched between a pair of transparent substrates. The liquid crystal display panel 10 includes, for example, a polarizer, a transparent substrate, pixel electrodes, an alignment film, a liquid crystal layer, an alignment film, a common electrode, a color filter, a transparent substrate (an opposed substrate) and a polarizer (all of which are not illustrated) in order from a side close to the illuminating device 20.

The transparent substrate is configured of a substrate transparent to visible light, for example, plate glass. In addition, an active drive circuit including TFTs (Thin Film Transistors) electrically connected to the pixel electrodes, wiring and the like is formed in the transparent substrate on a side close to the illuminating device 20 in the liquid crystal display panel 10. The pixel electrodes and the common electrode are made of, for example, ITO (Indium Tin Oxide). The pixel electrodes are arranged in a lattice arrangement or a delta arrangement on the transparent substrate, and function as electrodes for respective pixels. On the other hand, the common electrode is formed on a whole surface of the color filter, and functions as a common electrode facing the pixel electrodes. The alignment films are made of, for example, a polymer material such as polyimide, and performs an orientation process on a liquid crystal. The liquid crystal layer is made of, for example, a VA (Vertical Alignment) mode, TN (Twisted Nematic) mode or STN (Super Twisted Nematic) mode liquid crystal, and has a function of changing the direction of a polarizing axis of emitted light from the illuminating device 20 in each pixel by a voltage applied from the drive circuit. In addition, liquid crystal alignment is changed in a stepwise manner so that the direction of a transmission axis of each pixel is adjusted in a stepwise manner. In the color filter, color filters separating light passing through the liquid crystal layer into, for example, three primary colors of red (R), green (G) and blue (B), or four colors such as R, G, B and white (W), respectively, are arranged corresponding to the arrangement of the pixel electrodes. As a filter arrangement (a pixel arrangement), typically, a stripe arrangement, a diagonal arrangement, a delta arrangement or a rectangle arrangement is used. The polarizers are optical shutters of one kind, and allows only light (polarized light) in a certain vibration direction to pass therethrough. The polarizers are arranged so that their polarizing axes are different by 90° from each other, thereby the polarizers allow emitted light from the illuminating device 20 to pass therethrough via the liquid crystal layer, or block the emitted light.

Illuminating Device 20

The illuminating device 20 includes, for example, a light-emitting device 21 illustrated in FIG. 2A as a direct type light source. In addition, FIG. 2A illustrates a perspective view of the light-emitting device 21, and FIG. 2B illustrates an example of a sectional configuration taken along an arrow direction A-A in FIG. 2A. The light-emitting device 21 includes, for example, a substrate 22 and a light-emitting element 23. The light-emitting element 23 is formed on one surface of the substrate 22, more specifically a surface opposite to a surface facing the liquid crystal display panel 10 of the substrate 22. In other words, in the case where the light-emitting device 21 in FIG. 2A is applied as the illuminating device 20 in FIG. 1, the light-emitting element 23 is arranged below the substrate 22 in FIG. 1. The light-emitting element 23 is configured of, for example, an organic EL element, and is formed by laminating a transparent electrode 24, an organic EL layer 25 (a light-emitting layer) and a reflective electrode 26 in order from a side close to the substrate 22. The substrate 22 and the transparent electrode 24 are in contact with each other, and an interface 21B exists between the substrate 22 and the transparent electrode 24. A surface opposite to a surface facing the light-emitting element 23 of the substrate 22 is a light emission surface 21A of the light-emitting device 21, and is arranged to face the liquid crystal display panel 10. In FIG. 2A, the case where no component is particularly arranged on a light emission surface 21A is exemplified, but an optical sheet such as a prism sheet may be arranged on the light emission surface 21A.

Substrate 22

The substrate 22 is made of a material transparent to light generated in the organic EL layer 25, for example, glass, plastic or the like. The transmittance of the substrate 22 for light generated in the organic EL layer 25 is preferably approximately 70% or over. As plastic suitably applicable to the substrate 22, polyethylene terephthalate (PET), polyethylene naphthalate (PEN), polyimide, polycarbonate (PC) or the like is used. The substrate 22 preferably has rigidity (self-supporting property), but the substrate 22 may have flexibility.

For example, as illustrated in FIGS. 2A and 2B, the substrate 22 has, on a surface facing the transparent electrode 24, a concavo-convex structure 22A (a first concavo-convex structure) having regularity in one direction (an X-axis direction) in a laminate plane. The concavo-convex structure 22A is formed, for example, by arranging a plurality of strip-shaped protrusion sections 22B, which extend in a direction (a Y-axis direction) orthogonal to the X-axis direction, in parallel in the X-axis direction. As illustrated in FIG. 2B, for example, the protrusion sections 22B each preferably have a rounded top section 22C (a convex-curved surface). In the case where the top section 22C has a sharply pointed shape, a part corresponding to the top section 22C of the light-emitting element 23 is susceptible to damage due to coverage failure or the like, and the longevity of the light-emitting element 23 is reduced. In addition to the top section 22C, a depression section 22D formed by two adjacent protrusion sections 22B may be rounded (concave-curved). Thus, in the case where the top section 22C and the depression section 22D are rounded, the concavo-convex structure 22A has a wavy shape in an X-axis direction.

In addition, one or both of the top section 22C and the depression section 22D may be flat. A surface of a part between the top section 22C and the depression section 22D is preferably an inclined surface, but may be a perpendicular surface parallel to a laminate direction. The protrusion sections 22B may have various shapes such as a semicolumnar shape, a trapezoidal shape and a polygonal columnar shape. Moreover, all protrusion sections 22B may have the same shapes as one another, or adjacent protrusion sections 22B may have different shapes from each other. Further, a plurality of protrusion sections 22B on the substrate 22 are classified into two or more kinds of protrusion sections, and the two or more kinds of protrusion sections may have different shapes, respectively.

Scales in both of a thickness direction (a Z-axis direction) and an arrangement direction (an X-axis direction) of the protrusion section 22B are equal to or smaller than an upper wavelength limit (approximately 780 nm) of visible light (typically with a wavelength of approximately 380 nm to 780 nm both inclusive). In other words, the concavo-convex structure 22A has nano-order regularity or periodicity. In this case, each protrusion section 22B may have a width corresponding to a wavelength range of light generated in a part facing the protrusion section 22B of the organic EL layer 25, or a fixed width irrespective of the wavelength range of light generated in the part facing the protrusion section 22B of the organic EL layer 25.

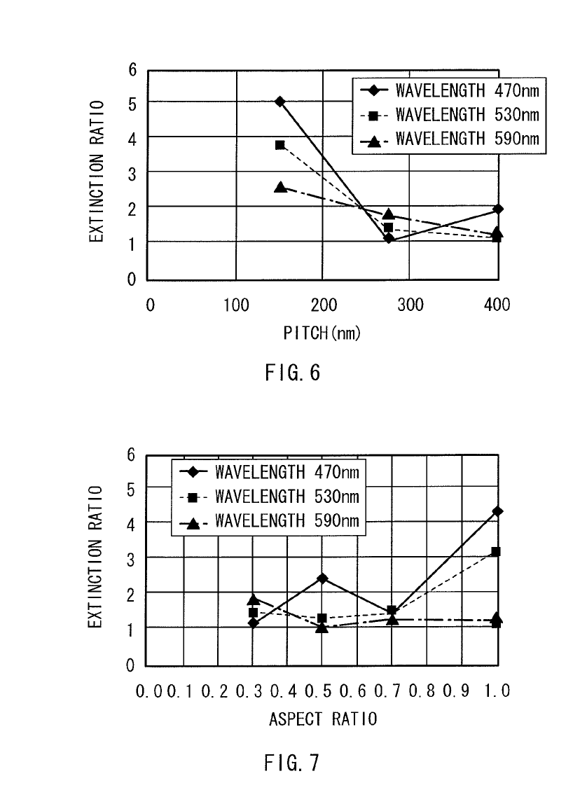

The height H of the protrusion section 22B is preferably within a range of 50 nm to 275 nm both inclusive, for example, within a range of 50 nm to 192.5 nm both inclusive. The width (a pitch P in an arrangement direction) of the protrusion section 22B is preferably within a range of 150 nm to 275 nm both inclusive. In particular, in the case where the pitch P is 275 nm or less, as illustrated in FIG. 6, polarized light with a high extinction ratio (a high polarization degree) is obtainable. Moreover, as illustrated in FIG. 7, in the case where an aspect ratio of 1.0 at which the extinction ratio is maximized is selected, the height H of the protrusion section 22B is preferably 275 nm or less. In addition, the aspect ratio of the depression section 22D determined by the height H and the width of the protrusion section 22B is preferably within a range of 0.2 to 2 both inclusive, because when the aspect ratio exceeds 2, it is difficult to laminate the light-emitting element 23 on the substrate 22, and when the aspect ratio is lower than 0.2, the refractive index in a laminate direction in the interface 21B and its surroundings changes abruptly, thereby a total reflection reduction effect which will be described later is almost eliminated.

Thus, the concavo-convex structure 22A geometric-optically has a surface shape close to a flat surface. However, as will be described later, the concavo-convex structure 22A exerts a specific function different from a mere flat surface or a concavo-convex structure having micro-order regularity. In addition, in the case where the substrate 22 is made of a resin, the concavo-convex structure 22A of the substrate 22 is allowed to be formed by, for example, nanoimprint technology. For example, the concavo-convex structure 22A is allowed to be formed by coating a supporting substrate with a resin which is a material of the substrate 22, and then pressing a die having a concavo-convex structure with a reverse shape of the concavo-convex structure 22A against the resin and applying heat or ultraviolet radiation to the resin. In the case where the substrate 22 is made of glass, for example, the concavo-convex structure 22A is allowed to be formed in the following steps. First, a glass surface is uniformly coated with a thermosetting resin or an ultraviolet curable resin. Next, a die having a concavo-convex structure with a reverse shape of the concavo-convex structure 22A is pressed against the resin, and the shape of the die is transferred to a surface of the resin by heat or ultraviolet radiation. Then, the surface is uniformly corroded (removed) by a reactive ion etching method or the like, thereby the concavo-convex structure 22A is allowed to be formed on the glass substrate. Further, for example, the concavo-convex structure 22A may be formed on the glass substrate by heating glass with a relatively low glass-transition temperature while pressing the glass against the above-described die.

Transparent Electrode 24

The transparent electrode 24 is made of a material transparent to light generated in the organic EL layer 25 and having conductivity. Examples of such a material include ITO (indium tin oxide), SnO (tin oxide), IZO (indium zinc oxide) and the like. The transparent electrode 24 is formed on a surface of the concavo-convex structure 22A of the substrate 22, and has a concavo-convex structure 24A (a second concavo-convex structure) imitating the concavo-convex structure 22A on a surface opposite to a surface facing the substrate 22. In other words, the concavo-convex structure 24A has nearly the same surface shape as that of the concavo-convex structure 22A, and has a surface shape of a concavo-convex structure in which protrusion sections similar to the protrusion section 22B are arranged in parallel in the X-axis direction. For example, in the concavo-convex structure 24A, the depth of a depression section 24B (a distance from the top of the protrusion section to the bottom of the depression section 24B) formed by two adjacent protrusion sections is equal to or smaller than the depth of the depression section 22D (a distance from the top of the protrusion section 22B to the bottom of the depression section 22D), and the aspect ratio of the depression section 24B is equal to or smaller than the aspect ratio of the depression section 22D. In order to secure good coverage such as the organic EL layer 25, the transparent electrode 24 and the reflective electrode 26, the depth of the depression section 24B is desirably equal to or smaller than the depth of the depression section 22D, but the depth of the depression section 24B may be larger than the depth of the depression section 22D. In addition, in the description, the meaning of “imitating” includes not only the case where concavo-convex structures have the same surface shapes but also the case where, as described above, the depths of the depression sections vary from one concavo-convex structure to another.

The thickness of the transparent electrode 24 preferably has a value at which the concavo-convex structure 24A having a scale equal to or smaller than the upper wavelength limit of visible light is formed when the transparent electrode 24 is formed on the substrate 22. The thickness of the transparent electrode 24 is preferably within a range of 50 nm to 500 nm both inclusive, and more preferably within a range of 80 nm to 150 nm both inclusive.

Organic EL Layer 25

The organic EL layer 25 has, for example, a laminate configuration in which a hole injection layer, a hole transport layer, a light-emitting layer and an electron transport layer are laminated in order from a side close to the transparent electrode 24. In addition, if necessary, the organic EL layer 25 may include any layer other than the above-described layers, or may not include one or both of the hole transport layer and the electron transport layer. In this case, the hole injection layer is provided to enhance hole injection efficiency. The hole transport layer is provided to enhance the hole transport efficiency to the light-emitting layer. The light-emitting layer emits light by the recombination of electrons and holes in response to the application of an electric field generated between the transparent electrode 24 and the reflective electrode 26. The electron transport layer is provided to enhance electron transport efficiency to the light-emitting layer. The organic EL layer 25 may generate light in one wavelength range (for example, a red range, a blue range or a green range), or may generate light in different wavelength ranges depending on position.

The organic EL layer 25 is formed on a surface of the concavo-convex structure 24A of the transparent electrode 24, and has, on a surface opposite to a surface facing the substrate 22, a shape approximately imitating the concavo-convex structure 24A. In other words, the organic EL layer 25 has a wavy shape (a concavo-convex structure) with a scale in the X-axis direction equal to or smaller than the upper wavelength limit of visible light. Thereby, in the organic EL layer 25 (specifically the light-emitting layer), a surface area per unit area viewed from the laminate direction is larger than that in the case where the organic EL layer 25 is formed on a flat surface. In addition, the organic EL layer 25 may be formed on a whole surface of the transparent electrode 24, or may be formed so as to be distributed in a pattern. The shape of the pattern is not specifically limited, and various shapes such as a matrix shape and a stripe shape may be used. In order to form waves with a scale equal to or smaller than the above-described upper wavelength limit of visible light when the organic EL layer 25 is formed on the transparent electrode 24, for example, the thickness of the organic EL layer 25 is preferably within a range of 50 nm to 780 nm both inclusive.

Reflective Electrode 26

The reflective electrode 26 is formed of a material reflecting light generated in the organic EL layer 25 with high reflectivity, for example, aluminum, platinum, gold, chromium, tungsten, nickel, an alloy including any one of them, or the like. The reflective electrode 26 is formed on a surface (a wavy surface) of the organic EL layer 25, and has, on a surface opposite to a surface facing the substrate 22, a shape approximately imitating waves on the surface of the organic EL layer 25. In other words, as in the case of the organic EL layer 25, the reflective electrode 26 has a wavy shape (a concavo-convex structure) with a scale in the X-axis direction equal to or smaller than the upper wavelength limit of visible light.

Next, functions and effects of the display 1 according to the embodiment will be described below.

In the embodiment, when a voltage is applied between the transparent electrode 24 and the reflective electrode 26, holes from the transparent electrode 24 and electrons from the reflective electrode 26 are introduced into the light-emitting layer in the organic EL layer 25. In the light-emitting layer, organic EL molecules are excited by the recombination of introduced holes and electrons to generate light with a predetermined wavelength. The generated light is planarly emitted from the light emission surface 21A to a back surface of the liquid crystal display panel 10 through the transparent electrode 24 and the substrate 22. In the liquid crystal display panel 10, incident light from the illuminating device 20 is modulated based on an image signal, and is separated into colors by the color filter, then the colors are emitted toward a viewing side. Thereby, a color image is displayed.

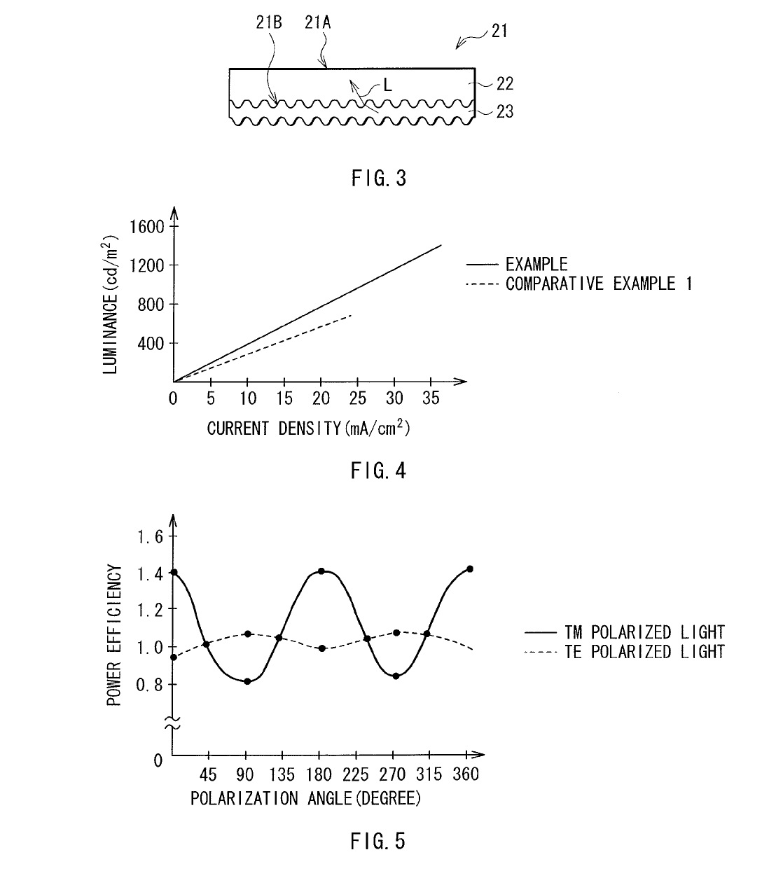

In the embodiment, the concavo-convex structure 22A having regularity in the X-axis direction equal to or smaller than the upper wavelength limit of visible light is arranged on a surface facing the transparent electrode 24 of the substrate 22. The transparent electrode 24, the organic EL layer 25 and the reflective electrode 26 each have, on a surface opposite to a surface facing the substrate 22, the concavo-convex structure 24A imitating the concavo-convex structure 22A. Typically, a difference in refractive index between the substrate 22 and the transparent electrode 24 is large, so in the case where the interface 21B between the substrate 22 and the transparent electrode 24 is flat, the reflectivity in the interface 21B is high. However, in the embodiment, the concavo-convex structure 22A having regularity equal to or smaller than the upper wavelength limit of visible light is arranged on the interface 21B, so in the interface 21B and its surroundings, a change in refractive index in the laminate direction is gentle. Thereby, the reflectivity in the interface 21B is reduced, so as illustrated in FIG. 3, the percentage of light L generated in the organic EL layer 25 which passes through the interface 21B to be emitted from the light emission surface 21A to outside is increased.

Moreover, in the embodiment, the concavo-convex structure 24A having regularity equal to or smaller than the upper wavelength limit of visible light is formed on the surface of the transparent electrode 24, so the organic EL layer 25 (specifically the light-emitting layer in the organic EL layer 25) has a wavy shape with a scale equal to or smaller than the upper wavelength limit of visible light. Thereby, compared to the case where the light-emitting layer has a flat shape, the surface area of the light-emitting layer is increased, thereby current density is increased. Moreover, the concavo-convex structure 24A having regularity equal to or smaller than the upper wavelength limit of visible light is formed in the transparent electrode 24, so parts where an electric field is locally strong with a scale equal to or smaller than the upper wavelength limit of visible light is regularly generated in the light-emitting layer. Thereby, compared to the case where the substrate 22 is flat, or the case where the concavo-convex structure having micro-order regularity is arranged in the substrate 22, both of current efficiency (=luminance/current density) and power efficiency (=luminance/(current densityx applied voltage)) are remarkably improved. Therefore, compared to the case where the substrate 22 is flat or the case where the concavo-convex structure having micro-order regularity is arranged in the substrate 22, luminance is allowed to be increased.

For example, it is obvious from FIG. 4 that in the case where the pitch of the protrusion section 22B is 275 nm (indicated by a solid line in FIG. 4; Example), compared to the case where the substrate 22 is flat (indicated by a broken line in FIG. 4; Comparative Example 1), luminance is higher.

Moreover, in the embodiment, the concavo-convex structure 22A having regularity in the X-axis direction equal to or smaller than the upper wavelength limit of visible light is arranged on a surface facing the transparent electrode 24 of the substrate 22. The transparent electrode 24, the organic EL layer 25 and the reflective electrode 26 each have, on a surface opposite to a surface facing the substrate 22, the concavo-convex structure 24A imitating the concavo-convex structure 22A. Thereby, light generated in the organic EL layer 25 (specifically the light-emitting layer in the organic EL layer 25) is converted into polarized light by the concavo-convex structure 22A on the surface of the substrate 22, or the transparent electrode 24, the organic EL layer 25 and the reflective electrode 26. Thereby, light emitted from the light-emitting element 23 is allowed to be converted into polarized light.

For example, in the case where the pitch of the protrusion section 22B is 275 nm, as illustrated in FIG. 5, a difference between the power efficiency of TM (Transverse Magnetic) polarized light (indicated by a solid line in FIG. 5) and power efficiency of TE (Transverse Electric) polarized light (indicated by a broken line in FIG. 5) is allowed to be increased. Then, when the difference in power efficiency is increased, the polarization degree of polarized light is allowed to be increased. In addition, TM polarized light means polarized light perpendicular to a lattice, and the TE polarized light means polarized light parallel to the lattice. Moreover, for example, in the case where the pitch of the protrusion section 22B is 275 nm, when the aspect ratio of the depression section 22D is in a range from 0.3 to 1.0, as illustrated in FIG. 7, in all of a red wavelength (590 nm), a green wavelength (530 nm) and a blue wavelength (470 nm), the extinction ratio is allowed to be larger than 1. Moreover, for example, in the case where the aspect ratio of the depression section 22D is 0.3, when the pitch of the protrusion section 22B is in a range from 150 nm to 400 nm, as illustrated in FIG. 6, in all of the red wavelength (590 nm), the green wavelength (530 nm) and the blue wavelength (470 nm), the extinction ratio is allowed to be larger than 1. In other words, as described above, when the extinction ratio is larger than (or smaller than) 1, the polarization degree is obtained. In addition, the extinction ratios illustrated in FIGS. 6 and 7 are derived by integrating the intensity of light in a front direction (more specifically light in an emission angle range of ±2.5°).

Thus, in the embodiment, without increasing the number of components or the thickness of the light-emitting device 21, polarized light is obtainable. Moreover, when polarized light is emitted from the light-emitting device 21, in the case where the polarization direction of the polarized light emitted from the light-emitting device 21 is parallel to the transmission axis of a polarizer on a side close to the light-emitting device 21 of the liquid crystal display panel 10, for example, the following effects are obtainable. Compared to the case where light entering the polarizer on a side close to the light-emitting device 21 is non-polarized light, display luminance is allowed to be increased. Moreover, compared to the case where light entering the polarizer on a side close to the light-emitting device 21 is non-polarized light, a polarization component intersecting (orthogonal to) the transmission axis of the polarizer on a side close to the light-emitting device 21 of the liquid crystal display panel 10 is allowed to be reduced, and contrast is allowed to be increased.

### Second Embodiment

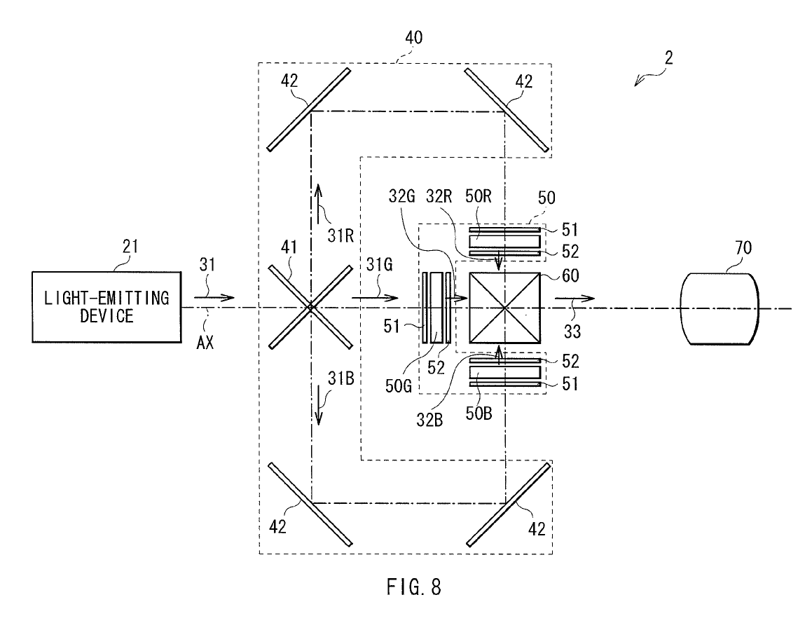

Next, a projector 2 according to a second embodiment will be described below. FIG. 8 illustrates an example of a schematic configuration of the projector 2 according to the embodiment. The projector 2 includes the light-emitting device 21 in the above-described embodiment as a light source of the projector 2.

The projector 2 is, for example, a three-panel transmissive LCD-projector, and as illustrated in FIG. 8, the projector 2 includes, for example, the light-emitting device 21, an optical path branch section 40, a spatial light modulation section 50, a synthesizing section 60 and a projection section 70.

The light-emitting device 21 supplies a luminous flux applied to an irradiated surface of the spatial light modulation section 50. In addition, if necessary, an optical element of some kind may be arranged in a region (on an optical axis AX) where light 31 from the light-emitting device 21 passes. For example, on the optical axis AX, an ND filter except for visible light from the light 31 from the light-emitting device 21, and an optical integrator making an illumination distribution on the irradiated surface of the spatial light modulation section 50 uniform may be arranged in this order from a side close to the light-emitting device 21.

The optical path branch section 40 separates the light 31 outputted from the light-emitting device 21 into a plurality of color light components having different wavelength ranges, respectively, to guide the color light components to the irradiated surface of the spatial light modulation section 50. For example, as illustrated in FIG. 8, the optical path branch section 40 includes one cross mirror 41 and four mirrors 42. The cross mirror 41 separates the light 31 outputted from the light-emitting device 21 into a plurality of color light components having different wavelength ranges, respectively, and allows an optical path to branch into optical paths for respective color light components. The cross mirror 41 is arranged, for example, on the optical axis AX, and is configured by combining two mirrors having different wavelength selectivity so as to cross each other. The four mirrors 42 reflect color light components (red light 31R and blue light 31B in FIG. 8) guided to respective optical paths by the cross mirror 41, and are arranged in positions different from the optical axis AX. Two mirrors 42 in the four mirrors 42 are arranged so as to guide light (the red light 31R in FIG. 8) reflected in one direction intersecting the optical axis AX by one mirror included in the cross mirror 41 to an irradiated surface of a spatial light modulation section 50R which will be described later. Moreover, the other two mirrors 42 in the four mirrors 42 are arranged so as to guide light (the blue light 31B in FIG. 8) reflected in another direction intersecting the optical axis AX by the other mirror included in the cross mirror 41 to an irradiated surface of a spatial light modulation section 50B which will be described later. In addition, light (green light 31G in FIG. 8) passing though the cross mirror 41 along the optical axis AX from the light 31 outputted from the light-emitting device 21 enters an irradiated surface of a spatial light modulation section 50G (which will be described later) arranged on the optical axis AX.

The spatial light modulation section 50 modulates each color light component to produce modulated light of each color light component in accordance with a modulation signal inputted from outside. The spatial light modulation section 50 includes, for example, the spatial light modulation section 50R modulating the red light 31R, the spatial light modulation section 50G modulating the green light 31G, and the spatial light modulation section 50B modulating the blue light 31B. The spatial light modulation section 50 further includes a pair of polarizers 51 and 52 between which the spatial light modulation sections 50R, 50G and 50B are sandwiched.

The spatial light modulation section 50R is, for example, a transmissive liquid crystal panel, and is arranged in a region facing one surface of the synthesizing section 60. The spatial light modulation section 50R generates red image light 32R by modulating incident red light 31R based on a modulation signal (a signal corresponding to an image signal), and then outputs the red image light 32R to the one surface of the synthesizing section 60 behind the spatial light modulation section 50R. The spatial light modulation section 50G is, for example, a transmissive liquid crystal panel, and is arranged in a region facing another surface of the synthesizing section 60. The spatial light modulation section 50G generates green image light 32G by modulating incident green light 31G based on a modulation signal (a signal corresponding to an image signal), and then outputs the green image light 32G to the another surface of synthesizing section 60 behind the spatial light modulation section 50G. The spatial light modulation section 50B is, for example, a transmissive liquid crystal panel, and is arranged in a region facing still another surface of the synthesizing section 60. The spatial light modulation section 50B generates blue image light 32B by modulating incident blue light 31B based on a modulation signal (a signal corresponding to an image signal), and then outputs the blue image light 32B to the still another surface of the synthesizing section 60 behind the spatial light modulation section 50B.

The polarizer 51 is a polarizer arranged on a light incident side of each of the spatial light modulation sections 50R, 50G and 50B, and the polarizer 52 is a polarizer arranged on a light emission side of each of the spatial light modulation sections 50R, 50G and 50B. The polarizers 51 and 52 are optical shutters of one kind, and allow only light (polarized light) in a certain fixed vibration direction to pass therethrough. The polarizers 51 and 52 are arranged so that their polarizing axes are different by 90° from each other, thereby the polarizers 51 and 52 allow light from the light-emitting device 21 to pass therethrough via the spatial light modulation sections 50R, 50G or 50B, or block the light from the light-emitting device 21.

The synthesizing section 60 generates image light by combining a plurality of modulated light components. The synthesizing section 60 is arranged, for example, on the optical axis AX, and is a cross prism configured of four prisms bonded together. Two selection reflective surfaces having different wavelength selectivity are formed of a multilayer interference film or the like on bonding surfaces of the prisms. One selection reflective surface reflects, for example, the red image light 32R outputted from the spatial light modulation section 50R in a direction parallel to the optical axis AX to guide the red image light 32R toward the projection section 70. Moreover, the other selection reflective surface reflects, for example, the blue image light 32B outputted from the spatial light modulation section 50B to a direction parallel to the optical axis AX to guide the blue image light 32B toward the projection section 70. Further, the green image light 32G outputted from the spatial light modulation section 50G passes through the two selection reflective surfaces to travel toward the projection section 70. The synthesizing section 60 functions so as to generate image light 33 by combining the red image light 32R, the green image light 32G and the blue image light 32B, which are generated in the spatial light modulation sections 50R, 50G and 50B, respectively, and then output the image light 33 to the projection section 70.

The projection section 70 projects the image light 33 outputted from the synthesizing section 60 on a screen (not illustrated) to display an image. The projection section 70 is arranged on, for example, the optical axis AX, and is configured of, for example, a projection lens.

In the embodiment, the light-emitting device 21 is used as a light source in the projector 2. Thereby, polarized light is obtainable without increasing the number of components in the light-emitting device 21 or the thickness of the light-emitting device 21, so the projector 2 is allowed to be downsized. Moreover, when polarized light is emitted from the light-emitting device 21, in the case where the polarization direction of polarized light emitted from the light-emitting device 21 is in parallel to a surface of the cross prism, for example, the following effects are obtainable. Compared to the case where light entering the polarizer on a side close to the light-emitting device 21 is non-polarized light, display luminance is allowed to be increased. Moreover, compared to the case where light entering the polarizer on a side close to the light-emitting device 21 is non-polarized light, a polarization component intersecting (orthogonal to) a surface of the cross prism is allowed to be reduced, and contrast is allowed to be increased.

Although the present application is described referring to the embodiments, the invention is not limited thereto, and may be variously modified.

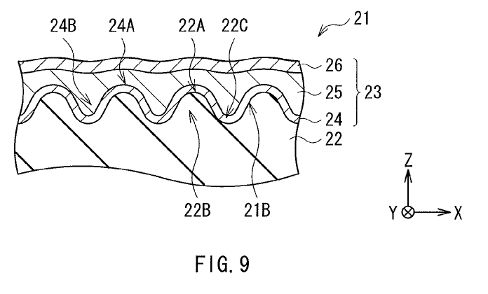

For example, in the above-described embodiments, surfaces, opposite to surfaces facing the substrate 22, of the organic EL layer 25 and the reflective electrode 26 have a wavy shape influenced by the protrusion sections 22B of the substrate 22. However, for example, as illustrated in a modification in FIG. 9, these surfaces may have an almost flat shape (that is, a gentle wavy shape).

Moreover, in the above-described embodiments, the case where the transparent electrode 24 and the reflective electrode 26 are used as an anode and a cathode, respectively, is described. However, the transparent electrode 24 and the reflective electrode 26 may be used as a cathode and an anode, respectively.

Further, in the above-described embodiments and the like, a plurality of protrusion sections 22B are arranged in parallel in the X-axis direction in the substrate 22. However, for example, pyramidal protrusion sections may be two-dimensionally arranged in the X-axis direction and the Y-axis direction.

In the above-described embodiments, the light-emitting element 23 is of a bottom emission type (a type where light is emitted from a bottom side (a side where a light-emitting layer or the like is not formed) of a substrate, refer to FIG. 1), but the light-emitting element 23 may be of a top emission type. In this case, in the above-described embodiments or the like, the transparent electrode 24 may be formed of the material of the reflective electrode 26, and the reflective electrode 26 may be formed of the material of the transparent electrode 24.

In addition, in the above-described embodiments, the case where the light-emitting device according to the invention is applied to a projector is described, but the light-emitting device is applicable to any other displays needing polarized light (such as a liquid crystal television and a liquid crystal monitor), various AV devices, illuminating devices, and the like.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A light-emitting device comprising:
a light-emitting element including, on a substrate, a first electrode, a light-emitting layer and a second electrode in order from the substrate,
wherein the substrate has, on a surface facing the first electrode, a first concavo-convex structure including a plurality of strip-shaped protrusion sections with a width equal to or smaller than an upper wavelength limit of visible light, and
the first electrode, the light-emitting layer and the second electrode each have, on a surface opposite to a surface facing the substrate, a second concavo-convex structure imitating the protrusion sections of the first concavo-convex structure.

2. The light-emitting device according to claim 1, wherein
the plurality of protrusion sections included in the first concavo-convex structure have the same shapes as one another.

3. The light-emitting device according to claim 1, wherein
the first concavo-convex structure includes two or more kinds of protrusion sections, and
the two or more kinds of the protrusion sections have different shapes, respectively.

4. The light-emitting device according to claim 1, wherein
the plurality of protrusion sections have equal pitches to one another.

5. The light-emitting device according to claim 1, wherein
the plurality of protrusion sections each have a width corresponding to a light emission wavelength of the light-emitting layer.

6. The light-emitting device according to claim 1, wherein
the first concavo-convex structure has an aspect ratio of 0.2 to 2 both inclusive.

7. The light-emitting device according to claim 1, wherein
the second concavo-convex structure of the first electrode has a rounded top section.

8. The light-emitting device according to claim 1, wherein
the substrate and the first electrode are formed of a material transparent to light generated in the light-emitting layer.

9. A display comprising:
a display panel driven based on an image signal; and
a light-emitting device emitting light which is applied to the display panel,
wherein the light-emitting device includes a substrate, and includes, on a surface opposite to a surface facing the display panel of the substrate, a first electrode, a light-emitting layer and a second electrode in order from the substrate,
the substrate has, on a surface facing the first electrode, a first concavo-convex structure including a plurality of strip-shaped protrusion sections with a width equal to or smaller than an upper wavelength limit of visible light, and
the first electrode, the light-emitting layer and the second electrode each have, on a surface opposite to a surface facing the substrate, a second concavo-convex structure imitating the protrusion sections of the first concavo-convex structure.
